(19) United States
(12) Patent Application Publication
(10) Pub. No.: US 2006/0136791 A1
(43) Pub. Date: Jun. 22, 2006

(54) Test method, control circuit and system for reduced time combined write window and retention testing

(76) Inventor: Klaus Nierle, Essex Junction, VT (US)

Correspondence Address: EDELL, SHAPIRO & FINNAN, LLC, 1901 RESEARCH BOULEVARD, SUITE 400, ROCKVILLE, MD, 20850, US

(21) Appl. No.: 11/012,322

(22) Filed: Dec. 16, 2004

(51) Int. Cl. G11C 29/00

(52) U.S. Cl. 714/718

(57) ABSTRACT

A method, test mode circuit and system for a combined write window and retention test for a memory device that is faster than techniques heretofore known. The combined write window and retention test procedure involves controlling time intervals during which wordlines are activated and deactivated and bitlines are grounded or connected to a bitline high voltage such that the wordlines are activated while bitlines are either grounded or at the bitline high voltage. During a first time interval after the wordlines are activated a first value (e.g., 0 V) is written to storage cells associated with the activated wordlines. During a second time interval after a second activation of the wordlines, a second value (a non-zero logic “1” V) is written to storage cells associated with activated wordlines. The second time interval has a duration that establishes write window test conditions. After expiration of a third time interval corresponding to a retention time interval, the storage cells are read and a determination is made whether a storage cell has passed or failed a combined write window and retention test based on a value read from the storage cell.

### FIELD OF THE INVENTIONS

This invention relates to testing semiconductor wafers, and more particularly to reducing the time required for testing semiconductor memory integrated circuit (IC) devices, such as dynamic random access memories (DRAMs).

### BACKGROUND OF THE INVENTION

In the complex manufacturing steps of semiconductor memory devices, such as DRAMs, defects may occur and it is critical to test for and discover such defects before final production and shipment. Two tests that are commonly performed are the “write window” test and the “retention test.” As is known in the art, the write window test consists of writing a signal to a memory cell in such a manner so as to cut short the time that the cell is permitted to otherwise charge completely. For example, the cell may be permitted to charge to only two-thirds of its final charged value. Measurements are then made concerning surrounding resistive and other properties under these conditions. A retention test consists of writing a logic “1” (i.e., a non-zero voltage) to a cell, waiting a time interval, then reading the cell to ensure that the voltage is retained by the cell.

Long test times result when performing both the write window test and retention test at the same time during DRAM production testing. For example, for a 512 Mbyte DDR chip with 16 input/output lines, the address range is 4 banks×8192 rows×1024 addresses. If all banks are tested in parallel, there are 8192 rows×512 column accesses required to test all storage cells with a limited write window. If combined with a retention test, this means performing a limited write of a voltage to the cells, and then waiting a specified retention time interval. This is further complicated in a wordline/bitline architecture.

One full page, that is one column address and all row addresses, can be initialized with a limited write window. However, if the column address is immediately incremented and rippled again through the row addresses and the previous column is refreshed, the retention time is lost. Therefore, with testing procedures heretofore known it is necessary to wait the full retention time multiplied by the number of column addresses. In this example, this would be 512 column addresses×64 ms retention time=32 sec+write/read overhead (approximately 1 sec). This is a significant length of time for volume production testing.

There is need for substantially reducing the time necessary for a combined write window and retention time testing procedure.

### SUMMARY OF THE INVENTION

Briefly, a method, test mode circuit and system for a combined write window and retention test for a memory device is provided that is faster than techniques heretofore known. The combined write window and retention test procedure involves controlling time intervals during which wordlines are activated and deactivated and bitlines are grounded or connected to a bitline high voltage such that the wordlines are activated while bitlines are either grounded or at the bitline high voltage. During a first time interval after the wordlines are activated, a first value (e.g., 0 V) is written to storage cells associated with the activated wordlines. During a second time interval after a second activation of the wordlines, a second value (a non-zero logic “1” V) is written to storage cells associated with the activated wordlines. The second time interval is shorter than the first time interval and has a duration that establishes write window test conditions. After expiration of a third time interval corresponding to a retention time interval, the storage cells are read and a determination is made whether a storage cell has passed or failed a combined write window and retention test based on a value read from the storage cell.

To achieve this test sequence, a test mode control circuit is provided comprising a main control circuit that receives as input trigger sequence signals and generates as output wordline activation control signals and bitline control signals to achieve a desired timing sequence for a combined write window and retention test of a memory device. A wordline control circuit is coupled to the main control circuit and is responsive to the wordline activation control signals to generate wordline activation signals and wordline deactivation signals that are supplied to wordlines associated with storage cells in the memory device. A sense amplifier control circuit is coupled to the main control circuit and is responsive to the bitline control signals to control the bitlines associated with the storage cells in the memory device.

The objects and advantages of the invention will become more readily apparent when reference is made to the following description taken in conjunction with the accompanied drawings, wherein like reference numerals in the various figures are utilized to designate like components.

### BRIEF DESCRIPTION OF THE DRAWINGS

FIG. 1 is a block diagram showing a portion of a memory device and a test mode control circuit that facilitates a faster combined write window and retention time testing procedure.

FIG. 2 is a block diagram of the test mode control circuit shown in FIG. 1.

FIG. 3 is a flow chart showing steps of the combined write window and retention time testing procedure.

FIG. 4 is a timing diagram of relevant signals during the combined write window and retention time testing procedure.

### DETAILED DESCRIPTION

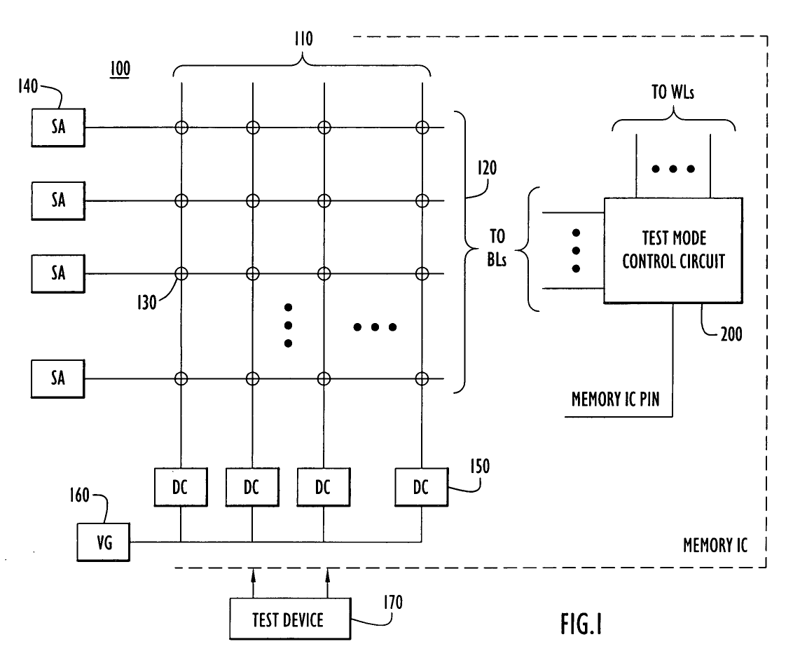

Referring first to FIG. 1, a portion or bank of a memory array is shown at reference numeral 100 that would be contained in a memory integrated circuit (IC) represented by the dotted line, such as a dynamic random access memory (DRAM) IC. There are a plurality of wordlines (WLs) 110 and a plurality of bitlines (BLs) 120 in a bank 100, and a plurality of banks in a memory IC. In a bank, the WLs 110 and BLs intersect at storage cells 130. There are many array configurations that are possible, and the test mode procedures described herein are not limited to the configuration shown in FIG. 1. Associated with the BLs 120 are sense amplifiers (SAs) 140. Associated with each WL are driver circuits (DCs) 150 that are used to activate and deactivate a corresponding WL. A voltage generator (VG) or source 160 is provided to supply the necessary voltages to activate and deactivate the WLs 110. Depending on some implementations, more than one VG may be needed for all of the WLs in a memory bank.

A test device 170 is coupled to the memory IC through means known in the art to perform a combined write window and retention testing procedure under control of the test mode control circuit 200. The test mode control circuit 200 controls the status of the WLs 110, BLs 120 and storage cells 130 in order to provide a fast combined write window and retention test suitable for use in volume production testing. The test mode control circuitry 200 does this by controlling the time interval during which all WLs in a portion or bank of the memory chip are activated and precharged while all BLs are either grounded (0V) or at a bitline high voltage level. A memory test system may be defined by a combination of the test mode control circuit 200 and the test device 170. The test mode control circuit 200 may be integrated on the memory IC as indicated by being contained within the dotted line in FIG. 1, or it may be integrated as part of the test device 170.

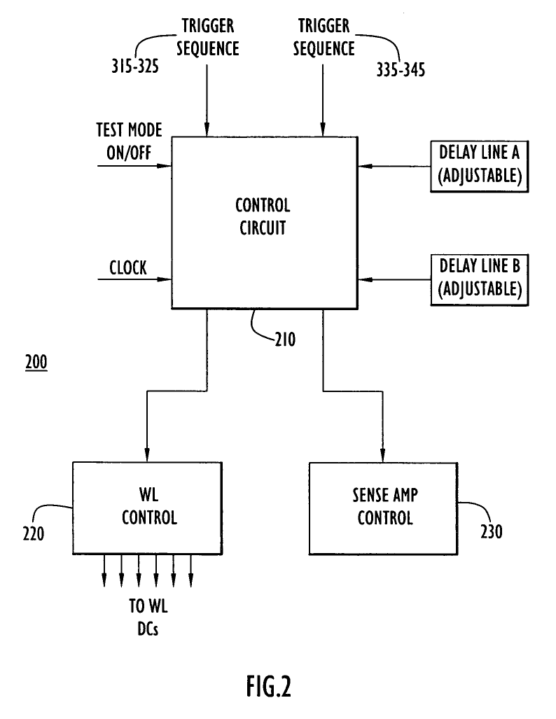

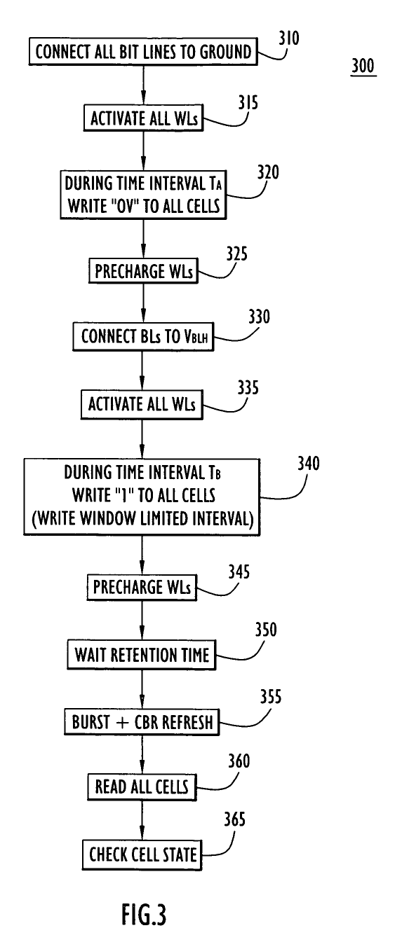

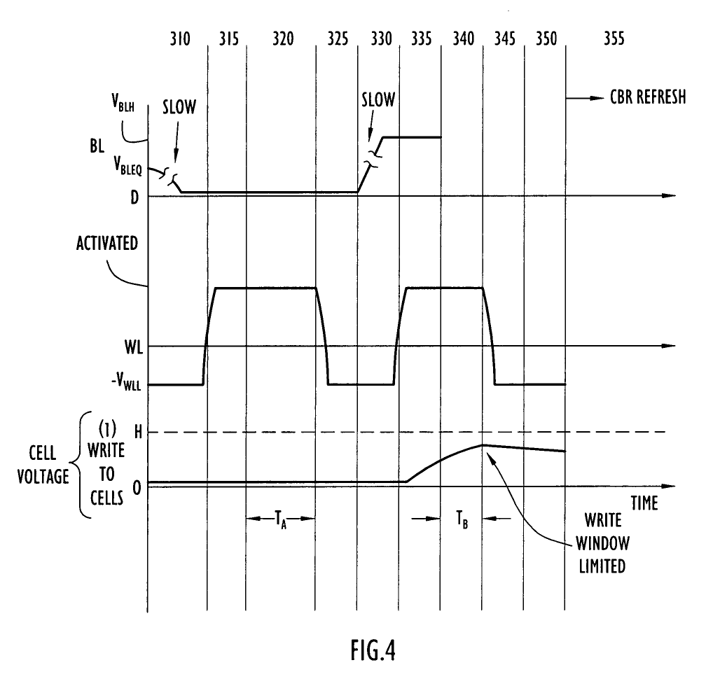

The test mode control circuit 200 is shown in more detail in FIG. 2. The test mode control circuit 200 comprises a main control circuit 210, a WL control block 220 and a sense amplifier control block 230. The main control circuit 210 has the following inputs: test mode on/off, clock, a first trigger sequence signal and a second trigger sequence signal. In addition, the control circuit 210 may receive two adjustable delay time period values on delay line A and delay line B, respectively, the purposes of which are explained hereinafter in connection with FIGS. 3 and 4. The source of the first and second trigger sequence signals may be the test device 170, and those signals may be coupled to the test mode control circuit 200 via an external pin, e.g. chip select or on-die-termination (ODT) pin on the memory IC if the test mode control circuit 200 is integrated in the memory IC.

The main control circuit 210, in response to the first and second trigger sequence signals, generates wordline activation control signals supplied to the WL control bock 220 that cause the WL control block 220 to activate and deactivate all (or a subset of) WLs associated with a bank of storage cells of the memory device. Similarly, the main control circuit 210 generates bitline control signals supplied to the sense amplifier control block 230 that in response supplies a signal to the sense amplifiers 140 (FIG. 1) to keep the BLs precharged. The main control circuit 210 generates the wordline activation control signals and bitline control signals to achieve a desired timing sequence for a combined write window and retention test. The WL control circuit is responsive to the wordline activation control signals to generate wordline activation signals and wordline deactivation signals that are supplied to DCs for wordlines associated with storage cells in the memory device. Likewise, the sense amplifier control circuit is responsive to the bitline control signals to control the bitlines associated with the storage cells.

As will become apparent from the following description of FIGS. 3 and 4, in response to the first and second trigger sequence signals, the main control circuit generates the wordline activation control signals and bitline control signals to cause the wordline control circuit and sense amplifier control circuit to control the status of the wordlines and bitlines to: connect the bitlines to ground; activate the wordlines; during a first time interval after activation write a first value to storage cells associated with the activated wordlines; deactivate the wordlines; connect the bitlines to a bitline high voltage; activate the wordlines; during a second time interval after activation write a second value to storage cells associated with the activated wordlines, wherein the second time interval has a duration that establishes write window test conditions; deactivate the wordlines; and after expiration of a third time interval corresponding to a retention time interval, read the storage cells.

The main control circuit 210, WL control circuit 220 and sense amplifier control circuit 230 may be implemented by digital logic gates, or their functions may be implemented in software.

With reference to FIGS. 3 and 4, the timing sequence 300 produced by the test mode control circuit for controlling the WLs, BLs and storage cells to perform a fast combined write window and retention test will be described. In step 310, all bitlines are connected to ground (0V). Next, in step 315, all wordlines are activated through their respective driver circuits. In step 320, a first time interval TA is provided during which 0V is written to all storage cells. The first time interval TA corresponds to the row address strobe (RAS) interval and is adjustable but nevertheless is sufficiently long for a normal or relaxed write window. Next, in step 325, the WLs are deactivated to a precharged state, i.e., connected to −V_{WLL} (negative wordline low voltage). In step 330, the bitlines are activated by connection to a high voltage, V_{BLH}. In step 335, the WLs are activated again and in step 340, a time interval T_{B} is provided corresponding to a shortened or limited write window interval. This time interval T_{B} is adjustable but is chosen to be sufficiently short in duration (shortened RAS interval) to establish critical write window conditions. During this time window, logic “1” (i.e., a non-zero voltage) is written to the storage cells associated with the activated wordlines. In step 345, the WLs are deactivated to a precharged state. Then, in step 350, a third time interval is provided corresponding to a retention time interval. Then, after the retention time interval, a burst CBR refresh is performed in step 355 to refresh the storage cells. After the CBR refresh, the test device 170 (FIG. 1) reads the storage cells in step 360. In step 365, the test device makes a determination whether the storage cells have passed the combined write window and retention test based on the content read from the storage cells. The test device may determine that the storage cell passes the test if the value of a storage cell is greater than a threshold, e.g., close to the non-zero voltage that was written to it, and otherwise determine that the storage cell fails the test if the value read from the cell is less than the threshold. This procedure is repeated for each bank of the memory device.

The bitline control steps 310 and 330 and the retention time and read steps 350 and 360, respectively, may be provided by a test mode feature that is part of an existing test device.

As an alternative, the procedure shown in FIG. 3 may be modified to perform a 0V write window/retention test whereby in step 340, 0V is written to the storage cells, instead of a non-zero voltage (“logic 1” ). Then, in step 365, the storage cell state is checked to see if is still 0V or sufficient close to 0V after the read operation in step 360.

To summarize, the combined write window and retention test procedure comprises: controlling time intervals during which wordlines are activated and deactivated and bitlines are grounded or connected to a bitline high voltage such that the wordlines are activated while bitlines are either grounded or at the bitline high voltage; during a first time interval after the wordlines are activated writing a first value to storage cells associated with the activated wordlines; during a second time interval after a second activation of the wordlines writing a second value to storage cells associated with activated wordlines, wherein the second time interval has a duration that establishes write window test conditions; after expiration of a third time interval corresponding to a retention time interval, reading the storage cells; and determining whether a storage cell has passed or failed a combined write window and retention test based on a value read from the storage cell.

Stated another way, the combined write window and retention time test procedure involves: connecting bitlines of the memory device to ground; activating wordlines of the memory device; during a first time interval after activating, writing a first value to storage cells associated with the activated wordlines; deactivating the wordlines; connecting the bitlines to a bitline high voltage; activating the wordlines of the memory device; during a second time interval after activating, writing a second value to storage cells associated with the activated wordlines, wherein the second time interval has a duration that establishes write window test conditions; deactivating the wordlines; after expiration of a third time interval corresponding to a retention time interval, reading the storage cells; and determining whether a storage cell has passed or failed a combined write window and retention test based on a value read from the storage cell.

In the example described above of a 512 Mbyte chip with 16 I/O (four banks of 8192 rows and 1024 columns), the time to complete the combined write window and retention test procedure for all four banks is:
4 banks*retention time=256 msec+overhead for steps 310-355(several hundred nsec)+read overhead (<0.5 sec).

The test mode control circuitry and procedure described above may be used to activate all wordlines at the same time in a bank, or if the internal voltage generator is not capable of activating all wordlines for a bank of storage cells at the same time, then a subset of wordlines in the bank may be activated in steps 315 and 335, and the other steps of the procedure are performed for each subset of wordlines.

Furthermore, the test mode control circuitry may be used to control the up-time of activated wordlines. The time interval T_{B}, corresponding to the write window time interval, is trimmable during test mode in order to establish a critical test point without causing false rejects.

The combined write window and retention test procedure described herein may be used for wafer level testing, burn-in testing and component level testing.

The system and methods described herein may be embodied in other specific forms without departing from the spirit or essential characteristics thereof. The foregoing embodiments are therefore to be considered in all respects illustrative and not meant to be limiting.

What is claimed is:

1. A method of performing a combined write window and retention test of a memory device, comprising:
a. connecting bitlines of the memory device to ground;
b. activating wordlines of the memory device;
c. during a first time interval after (b) of activating, writing a first value to storage cells associated with the activated wordlines;
d. deactivating the wordlines;
e. connecting the bitlines to a bitline high voltage;
f. activating the wordlines of the memory device;
g. during a second time interval after (f) of activating, writing a second value to storage cells associated with the activated wordlines, wherein the second time interval has a duration that establishes write window test conditions;
h. deactivating the wordlines;
i. after expiration of a third time interval corresponding to a retention time interval, reading the storage cells; and
j. determining whether a storage cell has passed or failed a combined write window and retention test based on a value read from the storage cell.

2. The method of claim 1, wherein determining comprises determining that a storage cell has passed the combined write window and retention test when a voltage greater than a threshold is read from the storage cell and determining that a storage cell has failed the combined write window and retention test when a voltage less than the threshold is read from the storage cell.

3. The method of claim 1, and further comprising refreshing the wordlines after expiration of the third time interval and prior to said determining.

4. The method of claim 1, wherein the first time interval corresponds to a row access strobe time interval, and the second time interval corresponds to a shortened row access strobe time interval.

5. The method of claim 4, and further comprising adjusting the first time interval and/or the second time interval.

6. The method of claim 1, wherein the first time interval corresponds to a relaxed write window and the second time interval is shorter than the first time interval.

7. The method of claim 1, wherein the memory device comprises a plurality of banks of storage cells, and wherein (a) through (j) are repeated for each bank of storage cells.

8. The method of claim 1, wherein (b) and (f) of activating comprise activating a plurality of wordlines associated with a bank of storage cells in the memory device.

9. The method of claim 1, wherein (b) and (f) of activating comprise activating a subset of the plurality of wordlines associated with a bank of storage cells.

10. The method of claim 8, and further comprising repeating (c) through (e) and (g) through (j) for each of a plurality of subsets of wordlines associated with the bank of storage cells.

11. The method of claim 1, wherein (c) writing comprises writing the first value comprises writing 0V to the storage cells and (g) writing the second value comprises writing a non-zero voltage to the storage cells.

12. The method of claim 1, wherein (g) writing the second value comprises writing 0V to the storage cells.

13. A test mode control circuit comprising:
a. a main control circuit that receives as input trigger sequence signals and generates as output wordline activation control signals and bitline control signals to achieve a desired timing sequence for a combined write window and retention test of a memory device;
b. a wordline control circuit coupled to the main control circuit and responsive to the wordline activation control signals to generate wordline activation signals and wordline deactivation signals that are supplied to wordlines associated with storage cells in the memory device; and
c. a sense amplifier control circuit coupled to the main control circuit and responsive to the bitline control signals to control the bitlines associated with the storage cells in the memory device.

14. The test mode control circuit of claim 13, wherein the main control circuit generates the wordline activation control signals and bitline control signals to cause the wordline control circuit and sense amplifier control circuit to control the status of the wordlines and bitlines to:
a. connect the bitlines to ground;
b. activate the wordlines;
c. during a first time interval after (b) of activation, write a first value to storage cells associated with the activated wordlines;
d. deactivate the wordlines;
e. connect the bitlines to a bitline high voltage;
f. activate the wordlines;
g. during a second time interval after (f) of activation, write a second value to storage cells associated with the activated wordlines, wherein the second time interval has a duration that establishes write window test conditions;
h. deactivate the wordlines; and
i. after expiration of a third time interval corresponding to a retention time interval, read the storage cells.

15. A test system comprising the test mode control circuit of claim 14, and further comprising a test device that determines whether a storage cell has passed or failed a combined write window and retention test based on a value read from the storage cell.

16. The test system of claim 15, wherein the test device determines that a storage cell has passed the combined write window and retention test when a voltage greater than a threshold is read from the storage cell and determines that a storage cell has failed the combined write window and retention test when a voltage less than the threshold is read from the storage cell.

17. The test mode control circuit of claim 14, wherein the main control circuit generates the first time interval and the second time interval based on programmable first and second values, respectively, and wherein the first time interval corresponds to a row access strobe time interval and the second time interval corresponds to a shortened row access strobe time interval.

18. The test mode control circuit of claim 14, wherein the main control circuit generates the wordline activation control signals and bitline control signals to repeat (a) through (i) for wordlines associated with each of a plurality of banks of storage cells.

19. The test mode control circuit of claim 14, wherein the main control circuit generates the wordline activation control signals and bitline control signals to, in (b) and (f), activate a subset of the wordlines associated with a bank of storage cells.

20. A memory test device comprising the test mode control circuit of claim 13.

21. A memory integrated circuit device comprising the test mode control circuit of claim 13.

22. A method of performing a combined write window test and a retention test of a memory device, comprising:
a. controlling time intervals during which wordlines are activated and deactivated and bitlines are grounded or connected to a bitline high voltage such that the wordlines are activated while bitlines are either grounded or at the bitline high voltage;
b. during a first time interval after the wordlines are activated writing a first value to storage cells associated with the activated wordlines;
c. during a second time interval after a second activation of the wordlines writing a second value to storage cells associated with activated wordlines, wherein the second time interval has a duration that establishes write window test conditions;
d. after expiration of a third time interval corresponding to a retention time interval, reading the storage cells; and
e. determining whether a storage cell has passed or failed a combined write window and retention test based on a value read from the storage cell.

23. The method of claim 22, wherein determining comprises determining that a storage cell has passed the combined write window and retention test when a voltage greater than a threshold is read from the storage cell and determining that a storage cell has failed the combined write window and retention test when a voltage less than the threshold is read from the storage cell.

24. The method of claim 22, and further comprising refreshing the wordlines after expiration of the third time interval and prior to said determining.

25. The method of claim 22, wherein the first time interval corresponds to a row access strobe time interval and the second time interval corresponds to a shortened row access strobe time interval.

26. The method of claim 1, wherein (b) writing the first value comprises writing 0V to the storage cells and (c) writing the second value comprises writing a non-zero voltage to the storage cells.

27. The method of claim 1, wherein (c) writing the second value comprises writing 0V to the storage cells.

28. A test mode control circuit comprising:
a. main controlling means responsive to input trigger sequence signals for generating as output wordline activation control signals and bitline control signals to achieve a desired timing sequence for a combined write window and retention test of a memory device;
b. wordline controlling means coupled to the main controlling means and responsive to the wordline activation control signals for generating wordline activation signals and wordline deactivation signals that are supplied to wordlines associated with storage cells in the memory device; and
c. sense amplifier controlling means coupled to the main controlling means and responsive to the bitline control signals to control the bitlines associated with the storage cells in the memory device.

29. The test mode control circuit of claim 27, wherein the main controlling means generates the wordline activation control signals and bitline control signals to cause the wordline controlling means and sense amplifier controlling means to control the status of the wordlines and bitlines in order to:
a. connect the bitlines to ground;
b. activate the wordlines;
c. during a first time interval after (b) of activation, write a first value to storage cells associated with the activated wordlines;
d. deactivate the wordlines;
e. connect the bitlines to a bitline high voltage;
f. activate the wordlines;
g. during a second time interval after (f) of activation, write a second value to storage cells associated with the activated wordlines, wherein the second time interval has a duration that establishes write window test conditions;
h. deactivate the wordlines; and
i. after expiration of a third time interval corresponding to a retention time interval, read the storage cells.
